(19) United States
(12) Patent Application Publication
(10) Pub. No.: US 2023/0044218 A1
(43) Pub. Date: Feb. 9, 2023

(54) DISPLAY DEVICE

(71) Applicant: Samsung Display Co., Ltd., Yongin-si (KR)

(72) Inventors: DAEWON KIM, Hwaseong-si (KR); SU JEONG KIM, Seoul (KR); JONGHO SON, Seoul (KR); JINHYEONG LEE, Suwon-si (KR); JI-YOON JUNG, Asan-si (KR)

(21) Appl. No.: 17/717,493

(22) Filed: Apr. 11, 2022

(30) Foreign Application Priority Data
Aug. 3, 2021 (KR) 10-2021-0101794

(51) Int. Cl. H01L 51/52

(52) U.S. Cl. CPC H01L 51/5281; H01L 51/5253; H01L 27/3246

(57) ABSTRACT

A display device includes: a base substrate, an emission element disposed on the base substrate, a capping layer disposed on the emission element and having a thickness of about 280 Å to about 360 Å, an anti-reflection layer disposed on the capping layer, a filling layer disposed on the anti-reflection layer and having a refractive index of about 1.3 to about 1.6, and an encapsulation substrate disposed on the filling layer.

This application claims priority to Korean Patent Application No. 10-2021-0101794, filed on Aug. 3, 2021, and all the benefits accruing therefrom under 35 U.S.C. § 119, the content of which in its entirety is herein incorporated by reference.

### BACKGROUND

### 1. Field

Embodiments provide generally to a display device. More particularly, embodiments relate to a display device that provides visual information.

### 2. Description of the Related Art

A flat panel display (“FPD”) having a large area and capable of being thin and light has been widely used as a display device. As the flat panel display, a liquid crystal display device (“LCD”), a plasma display panel (“PDP”), an organic light emitting display device (“OLED”), and the like are used.

The organic light emitting display device may include a plurality of metal patterns or metal layers, and thus external light may be reflected. In order to prevent reflection of the external light, a polarizing plate is generally used. However, although the polarizing plate may prevent reflection of the external light, the polarizing plate causes a decrease in transmittance of light emitted from the inside of the organic light emitting display device.

### SUMMARY

Embodiment provides a display device with improved display quality.

A display device according to an embodiment includes: a base substrate; an emission element disposed on the base substrate; a capping layer disposed on the emission element and having a thickness of about 280 angstroms (Å) to about 360 Å; an anti-reflection layer disposed on the capping layer; a filling layer disposed on the anti-reflection layer and having a refractive index of about 1.3 to about 1.6; and an encapsulation substrate disposed on the filling layer.

In an embodiment, the display device may further include a reflection adjusting layer disposed on the encapsulation substrate.

In an embodiment, the anti-reflection layer may include an inorganic material and the reflection adjusting layer may include an organic material.

In an embodiment, the filling layer may include a transparent material.

In an embodiment, the transparent material may include at least one selected from a group consisting of a silicone-based resin and an acrylic resin.

In an embodiment, the filling layer further may include any one selected from a group consisting of a scatterer, a dye, and an ultraviolet absorber.

In an embodiment, the display device may further include a sealing member disposed between the base substrate and the encapsulation substrate and which couples the base substrate and the encapsulation substrate.

In an embodiment, each of the base substrate and the encapsulation substrate may include a glass.

In an embodiment, the emission element may include: a lower electrode disposed on the base substrate; an organic emission layer disposed on the lower electrode; and an upper electrode disposed on the organic emission layer.

In an embodiment, the refractive index of the filling layer may be the same as a refractive index of the anti-reflection layer or a refractive index of the capping layer.

A display device according to an embodiment includes: a base substrate; an emission element disposed on the base substrate; a capping layer disposed on the emission element and having a thickness of about 630 Å to about 710 Å; an anti-reflection layer disposed on the capping layer; a filling layer disposed on the anti-reflection layer and having a refractive index of about 1.7 to about 2.1; and an encapsulation substrate disposed on the filling layer.

In an embodiment, the display device may further include a reflection adjusting layer disposed on the encapsulation substrate.

In an embodiment, the anti-reflection layer may include an inorganic material and the reflection adjusting layer may include an organic material.

In an embodiment, the filling layer may include a transparent material.

In an embodiment, the transparent material may include at least one selected from a group consisting of a silicone-based resin and an acrylic resin.

In an embodiment, the filling layer may further include any one selected from a group consisting of a scatterer, a dye, and an ultraviolet absorber.

In an embodiment, the display device may further include a sealing member disposed between the base substrate and the encapsulation substrate and which couples the base substrate and the encapsulation substrate.

In an embodiment, each of the base substrate and the encapsulation substrate may include a glass.

In an embodiment, the emission element may include: a lower electrode disposed on the base substrate; an organic emission layer disposed on the lower electrode; and an upper electrode disposed on the organic emission layer.

In an embodiment, the refractive index of the filling layer may be the same as a refractive index of the anti-reflection layer or a refractive index of the capping layer.

In a display device according to an embodiment of the present disclosure, a capping layer may have a thickness of about 280 Å to about 360 Å, and a filling layer may have a refractive index of about 1.3 to about 1.6. Accordingly, the reflectance of the display device by external light may be reduced. Accordingly, a display quality of the display device may be effectively improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a cross-sectional view taken along line I-I′ of FIG. 1.

FIG. 3 is an enlarged cross-sectional view of area “A” of FIG. 2.

FIGS. 4, 5, 6, and 7 are cross-sectional views illustrating a method of manufacturing the display device of FIG. 1.

FIG. 8 is a cross-sectional view illustrating a display device according to another embodiment.

FIGS. 9 and 10 are diagrams illustrating reflectance of a display device obtained according to examples and comparative example.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Hereinafter, embodiments of the present disclosure will be explained in detail with reference to the accompanying drawings. The same reference numerals are used for the same components in the drawings, and redundant descriptions of the same components will be omitted.

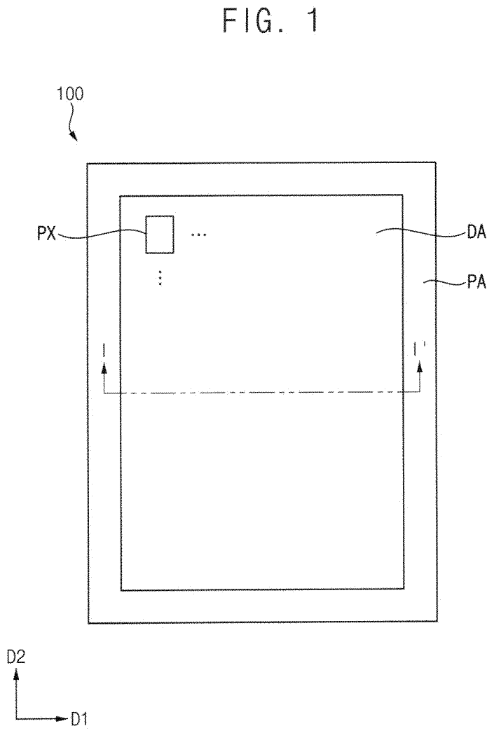

FIG. 1 is a plan view illustrating a display device according to an embodiment.

Referring to FIG. 1, the display device 100 may include a display area DA and a peripheral area PA adjacent to the display area DA. The peripheral area PA may surround at least a portion of the display area DA. For example, the peripheral area PA may surround the entirety of the display area DA. The display area DA may be defined as an area capable of displaying an image by generating light or adjusting transmittance of light provided from an external light source. The peripheral area PA may be defined as an area that does not display an image.

A plurality of pixels PX may be disposed in the display area DA. The plurality of pixels PX may generate light according to a driving signal. The plurality of pixels PX may be arranged in a first direction D1 and a second direction D2 crossing the first direction D1.

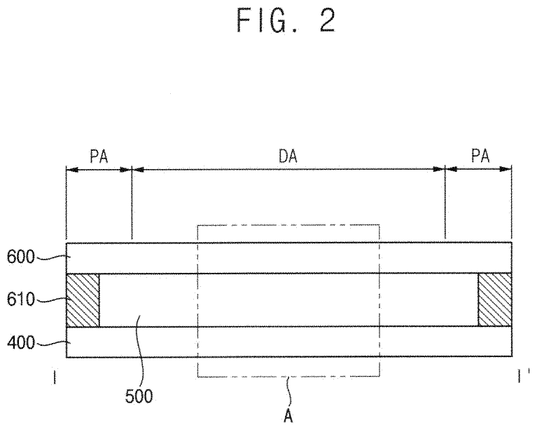

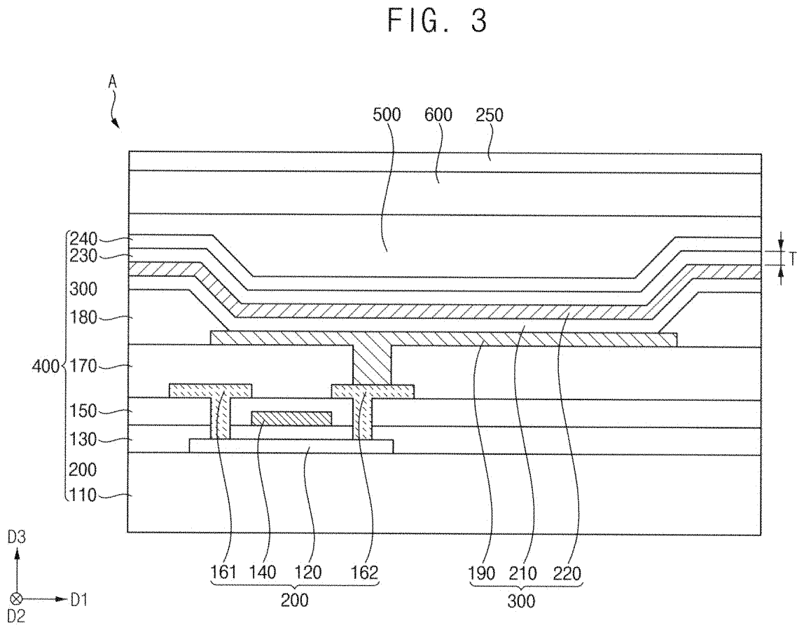

FIG. 2 is a cross-sectional view taken along line I-I′ of FIG. 1. FIG. 3 is an enlarged cross-sectional view of area “A” of FIG. 2.

Referring to FIGS. 2 and 3, the display device 100 may include a display substrate 400, a filling layer 500, a sealing member 610, an encapsulation substrate 600, and a reflection adjusting layer 250. Here, the display substrate 400 may include a base substrate 110, a gate insulating layer 130, a driving element 200, an interlayer-insulating layer 150, a planarization layer 170, a pixel defining layer 180, an emission element 300, a capping layer 230, and an anti-reflection layer 240. The driving element 200 may include an active layer 120, a gate electrode 140, a source electrode 161, and a drain electrode 162. The emission element 300 may include a lower electrode 190, an emission layer 210, and an upper electrode 220.

The base substrate 110 may include a transparent material or an opaque material. In an embodiment, the base substrate 110 may include a quartz substrate, a synthetic quartz substrate, a calcium fluoride substrate, a fluorine-doped quartz substrate, a soda-lime glass substrate, an alkali-free substrate, a non-alkali glass substrate, or the like. These may be used alone or in combination with each other.

A buffer layer may be disposed between the base substrate 110 and the driving element 100. The buffer layer may prevent diffusion of metal atoms or impurities from the base substrate 110 to the driving element 200. In addition, when a surface of the base substrate 110 is not uniform, the buffer layer may improve a flatness of the surface of the base substrate 110. For example, the buffer layer may include an organic material or an inorganic material.

The active layer 120 of the driving element 200 may be disposed in the display area DA on the base substrate 110. The active layer 120 may include a metal oxide, an inorganic semiconductor (e.g., amorphous silicon, polysilicon), or an organic semiconductor. The active layer 120 may have a source region, a drain region, and a channel region. The channel region may be positioned between the source region and the drain region.

The gate insulating layer 130 may be disposed on the base substrate 110 and the active layer 120. The gate insulating layer 130 may cover the active layer 120. The gate insulating layer 130 may include a silicon compound, a metal oxide, or the like. Examples of the silicon compound that can be used for the gate insulating layer 130 may be silicon oxide (SiOₓ), silicon nitride (SiNₓ), silicon carbide (SiCₓ), silicon oxynitride (SiOₓN_{y}), silicon oxycarbide (SiOₓC_{y}), or the like. In addition, examples of the metal oxide that can be used for the gate insulating layer 130 may be aluminum oxide (AlO), aluminum nitride (AlN), tantalum oxide (TaO), hafnium oxide (HfO), zirconium oxide (ZrO), titanium oxide. (TiO), or the like. Each of these may be used alone or in combination with each other. In another embodiment, the gate insulating layer 130 may have a multilayer structure including a plurality of insulating layers. For example, the insulating layers may have different thicknesses or may include different materials from each other.

The gate electrode 140 may be disposed in the display area DA on the gate insulating layer 130. The gate electrode 140 may overlap the channel region of the active layer 120 in a plan view. Here, the plan view is a view from a third direction D3 which is perpendicular to the second direction D2 and the first direction D1. For example, the gate electrode 140 may include a metal, an alloy, a metal nitride, a conductive metal oxide, a transparent conductive material, or the like. These may be used alone or in combination with each other. In another embodiment, the gate electrode 140 may have a multilayer structure including a plurality of metal layers. For example, the metal layers may have different thicknesses or may include different materials from each other.

The interlayer-insulating layer 150 may be disposed on the gate insulating layer 130 and the gate electrode 140. The interlayer-insulating layer 150 may cover the gate electrode 140. The interlayer-insulating layer 150 may include a silicon compound, a metal oxide, or the like. Examples of the silicon compound that can be used for the interlayer-insulating layer 150 may be silicon oxide, silicon nitride, or the like. In addition, examples of the metal oxide that can be used for the interlayer-insulating layer 150 may be aluminum oxide, aluminum nitride, tantalum oxide, or the like. Each of these may be used alone or in combination with each other. In another embodiment, the interlayer-insulating layer 150 may have a multilayer structure including a plurality of insulating layers. For example, the insulating layers may have different thicknesses or may include different materials from each other.

The source electrode 161 and the drain electrode 162 may be disposed in the display area DA on the interlayer-insulating layer 150. The source electrode 161 may be connected to the source region of the active layer 120 through a first contact hole. The drain electrode 162 may be connected to the drain region of the active layer 120 through a second contact hole. For example, each of the source electrode 161 and the drain electrode 162 may include a metal, an alloy, a metal nitride, a conductive metal oxide, a transparent conductive material, or the like. These may be used alone or in combination with each other. In another embodiment, each of the source electrode 161 and the drain electrode 162 may have a multilayer structure including a plurality of metal layers. For example, the metal layers may have different thicknesses or may include different materials from each other.

The planarization layer 170 may be disposed on the interlayer-insulating layer 150, the source electrode 161, and the drain electrode 162. The planarization layer 170 may sufficiently cover the source electrode 161 and the drain electrode 162. The planarization layer 170 may include an organic material or an inorganic material. Examples of the organic material that can be used for the planarization layer 170 may be a photoresist, a polyacryl-based resin, a polyimide-based resin, and a polyamide-based resin, a siloxane-based resin, an acryl-based resin, an epoxy-based resin, or the like. These may be used alone or in combination with each other.

The lower electrode 190 may be disposed in the display area DA on the planarization layer 170. The lower electrode 190 may be connected to the drain electrode 162 through a contact hole. In an embodiment, the lower electrode 190 may be an anode electrode. The lower electrode 190 may include a metal, an alloy, a metal nitride, a conductive metal oxide, a transparent conductive material, or the like. These may be used alone or in combination with each other. In another embodiment, the lower electrode 190 may have a multilayer structure including a plurality of metal layers. For example, the metal layers may have different thicknesses or may include different materials from each other.

The pixel defining layer 180 may be disposed in the display area DA on the planarization layer 170 and the lower electrode 190. The pixel defining layer 180 may cover both sides of the lower electrode 190 and may expose a portion of an upper surface of the lower electrode 190. The pixel defining layer 180 may include an organic material or an inorganic material. In an embodiment, the pixel defining layer 180 may include an organic material.

The emission layer 210 may be disposed in the display area DA on the pixel defining layer 180 and the lower electrode 190. The emission layer 210 may include a hole injection layer (“HIL”), a hole transporting layer (“HTL”), an organic emission layer (“EML”), an electron transporting layer (“ETL”), an electron injection layer (“EIL”), or the like. The organic emission layer may emit red light, green light, or blue light. Alternatively, when the organic emission layer emits white light, the organic emission layer may include a multilayer structure including a red organic emission layer, a green organic emission layer, and a blue organic emission layer, or a mixed layer of red, green, and blue light emitting materials. For example, the organic emission layer may include a low molecular weight organic compound or a high molecular weight organic compound. The emission layer 210 may be referred to as an organic emission layer.

The upper electrode 220 may be disposed in the display area DA on the emission layer 210. The upper electrode 220 may include a metal, an alloy, a metal nitride, a conductive metal oxide, a transparent conductive material, or the like. These may be used alone or in combination with each other. In another embodiment, the upper electrode 220 may have a multilayer structure including a plurality of metal layers. For example, the metal layers may have different thicknesses or may include different materials from each other. In an embodiment, the upper electrode 220 may be a cathode electrode.

The capping layer 230 may be disposed on the upper electrode 220. The capping layer 230 may be disposed on the entirety of the upper electrode 220. The capping layer 230 may function to protect the upper electrode 220. For example, the capping layer 230 may include an organic material or an inorganic material.

The anti-reflection layer 240 may be disposed on the capping layer 230. The anti-reflection layer 240 may be disposed on the entirety of the capping layer 230. The anti-reflection layer 240 may include an inorganic material, or the like. Examples of the material that can be used for the anti-reflection layer 240 may be silicon dioxide (SiO₂), titanium dioxide (TiO₂), bismuth oxide (Bi₂O₃), or the like. These may be used alone or in combination with each other. In another embodiment, the anti-reflection layer 240 may be patterned to include a plurality of anti-reflection layers.

The filling layer 500 may be disposed on the anti-reflection layer 240. Specifically, the filling layer 500 may be disposed in the display area DA and a portion of the peripheral area PA on the anti-reflection layer 240. The filling layer 500 may include a transparent material. In an embodiment, the filling layer 500 may include a silicone-based resin, an acrylic resin, or the like. These may be used alone or in combination with each other. In this case, the refractive index of the filling layer 500 may be about 1.3 to about 1.6.

In an embodiment, the refractive index of the filling layer 500 may be substantially the same as the refractive index of the anti-reflection layer 240 or the refractive index of the capping layer 230. In this case, the refractive index of the anti-reflection layer 240 or the refractive index of the capping layer 230 may be about 1.3 to about 1.6.

In an embodiment, the filling layer 500 may further include any one of a scatterer, a dye, and an ultraviolet absorber. Accordingly, the display quality of the display device 100 may be further improved.

In an embodiment, when the thickness T of the capping layer 230 is about 280 angstroms (Å) to about 360 Å, the refractive index of the filling layer 500 may be about 1.3 to about 1.6. When the thickness T of the capping layer 230 is less than about 280 Å or greater than about 360 Å in a case that the refractive index of the filling layer 500 may be about 1.3 to about 1.6, the reflectance of the display device 100 by external light may increase. In addition, when the refractive index of the filling layer 500 is less than about 1.3 or greater than about 1.6 in a case that the thickness T of the capping layer 230 is about 280 Å to about 360 Å, the reflectance of the display device 100 by external light may increase. Here, the thickness T is measured in the third direction D3.

The sealing member 610 may be disposed in the peripheral area PA on the display substrate 400. Specifically, the sealing member 610 may be disposed in the peripheral area PA on the base substrate 110. The sealing member 610 may be disposed between the base substrate 110 and the encapsulation substrate 600. The sealing member 610 may be disposed along edges of the base substrate 110 and the encapsulation substrate 600 in the peripheral area PA to surround the display area DA in a plan view. In addition, the base substrate 110 and the encapsulation substrate 600 may be coupled to each other though the sealing member 610. The sealing member 610 may include an organic material. For example, the sealing member 610 may include an epoxy-based resin or the like.

The encapsulation substrate 600 may be disposed on the filling layer 500 and the sealing member 610. The encapsulation substrate 600 may prevent penetration of external moisture and oxygen to the filling layer 500. The encapsulation substrate 600 may include a transparent material or an opaque material. In an embodiment, the encapsulation substrate 600 may include a quartz substrate, a synthetic quartz substrate, a calcium fluoride substrate, a fluorine-doped quartz substrate, a soda-lime glass substrate, and an alkali-free substrate, a non-alkali glass substrate or the like. These may be used alone or in combination with each other.

The reflection adjusting layer 250 may be disposed on the encapsulation substrate 600. The reflection adjusting layer 250 may be disposed on the entirety of the encapsulation substrate 600. In this case, a polarizer may not be disposed on the encapsulation substrate 600. The reflection adjusting layer 250 may include an organic material or the like. For example, the reflection adjusting layer 250 may include a light absorbing material. In another embodiment, the reflection adjusting layer 250 may be patterned to include a plurality of reflection adjustment layers.

However, although the display device 100 of the present disclosure is described as an organic light emitting display display, the configuration of the present disclosure is not limited thereto. In other embodiments, the display device 100 may include a liquid crystal display device (“LCD”), a field emission display device (“FED”), a plasma display device (“PDP”), or an electrophoretic image display device (“EPD”).

In a conventional display device, a vacuum layer is generated under an encapsulation substrate, and optical loss occurs due to the vacuum layer. That is, the reflectance of the display device by external light is increased due to the vacuum layer. In order to reduce the reflectance of the display device, a filling layer is provided by filling the vacuum layer with a transparent material.

In the display device 100 according to an embodiment of the present disclosure, the thickness T of the capping layer 230 may be about 280 Å to about 360 Å, and the refractive index of the filling layer 500 may be about 1.3 to about 1.6. Accordingly, the reflectance of the display device 100 by external light may be reduced. Accordingly, the display quality of the display device 100 may be effectively improved.

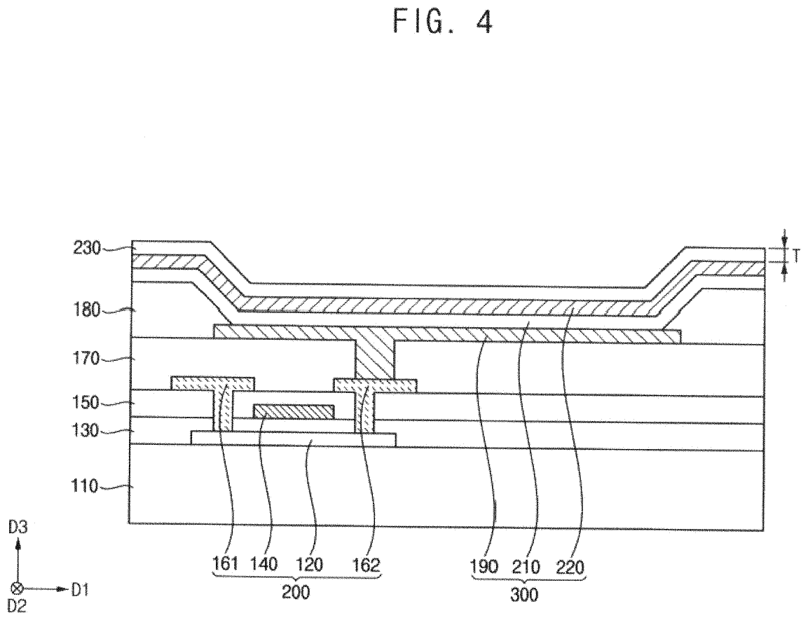

FIGS. 4, 5, 6, and 7 are cross-sectional views illustrating a method of manufacturing the display device of FIG. 1.

Referring to FIG. 4, the buffer layer may be formed on the base substrate 110. The base substrate 110 may include a transparent material or an opaque material. The buffer layer may be entirely formed on the base substrate 110. The buffer layer may include an organic material or an inorganic material.

The active layer 120 may be formed in the display area DA on the base substrate 110. The active layer 120 may include a metal oxide, an inorganic semiconductor, or an organic semiconductor.

The gate insulating layer 130 may be formed on the base substrate 110. The gate insulating layer 130 may cover the active layer 120. The gate insulating layer 130 may include a silicon compound, a metal oxide, or the like.

The gate electrode 140 may be formed in the display area DA on the gate insulating layer 130. The gate electrode 140 may be formed to overlap the active layer 120. The gate electrode 140 may include a metal, an alloy, a metal nitride, a conductive metal oxide, a transparent conductive material, or the like.

The interlayer-insulating layer 150 may be formed on the gate insulating layer 130. The interlayer-insulating layer 150 may cover the gate electrode 140. The interlayer-insulating layer 150 may include a silicon compound, a metal oxide, or the like.

The source electrode 161 and the drain electrode 162 may be formed in the display area DA on the interlayer-insulating layer 150. The source electrode 161 may be connected to the source region of the active layer 120 through a first contact hole formed by removing a first portion of the interlayer-insulating layer 150 and the gate insulating layer 130. The drain electrode 162 may be connected to the drain region of the active layer 120 through a second contact hole formed by removing a second portion of the interlayer-insulating layer 150 and the gate insulating layer 130. Each of the source electrode 161 and the drain electrode 162 may include a metal, an alloy, a metal nitride, a conductive metal oxide, a transparent conductive material, or the like.

The planarization layer 170 may be formed on the interlayer-insulating layer 150. The planarization layer 170 may be formed to sufficiently cover the source electrode 161 and the drain electrode 162. For example, the planarization layer 170 may include an organic material.

The lower electrode 190 may be formed in the display area DA on the planarization layer 170. The lower electrode 190 may be connected to the drain electrode 162 through a contact hole formed by removing a portion of the planarization layer 170. The lower electrode 190 may include a metal, an alloy, a metal nitride, a conductive metal oxide, a transparent conductive material, or the like. The pixel defining layer 180 may be formed on the planarization layer 170 and the lower electrode 190. For example, the pixel defining layer 180 may include an organic material.

The emission layer 210 may be formed on the pixel defining layer 180 and the lower electrode 190. The emission layer 210 may be entirely formed in the display area DA. The upper electrode 220 may be formed on the emission layer 210. The upper electrode 220 may be entirely formed in the display area DA. The upper electrode 220 may include a metal, an alloy, a metal nitride, a conductive metal oxide, a transparent conductive material, or the like.

The capping layer 230 may be formed on the upper electrode 220. The capping layer 230 may be entirely formed on the upper electrode 220. The capping layer 230 may include an organic material or an inorganic material.

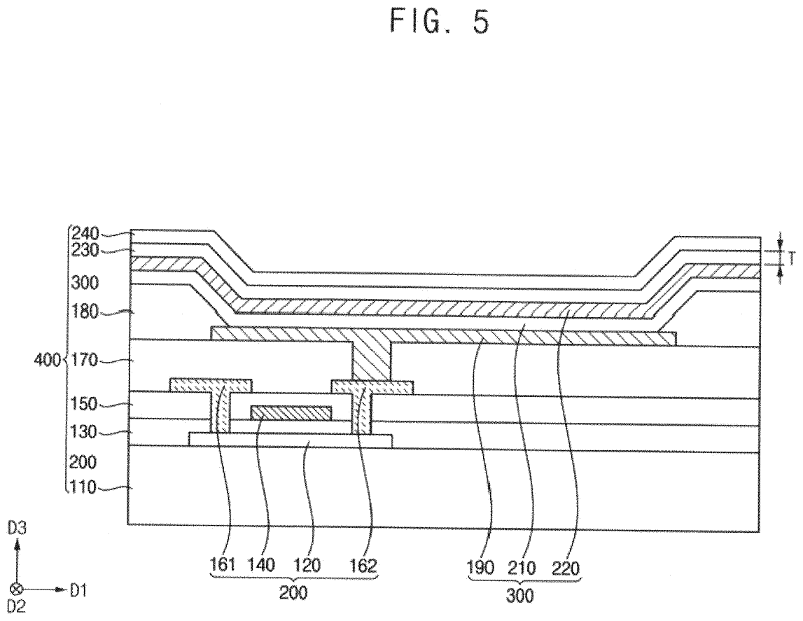

Referring to FIG. 5, the anti-reflection layer 240 may be formed on the capping layer 230. The anti-reflection layer 240 may be entirely formed on the capping layer 230. The anti-reflection layer 240 may include an inorganic material or the like. In another embodiment, after the entire inorganic layer is formed on the capping layer 230, a plurality of anti-reflection layers may be formed by patterning the inorganic layer.

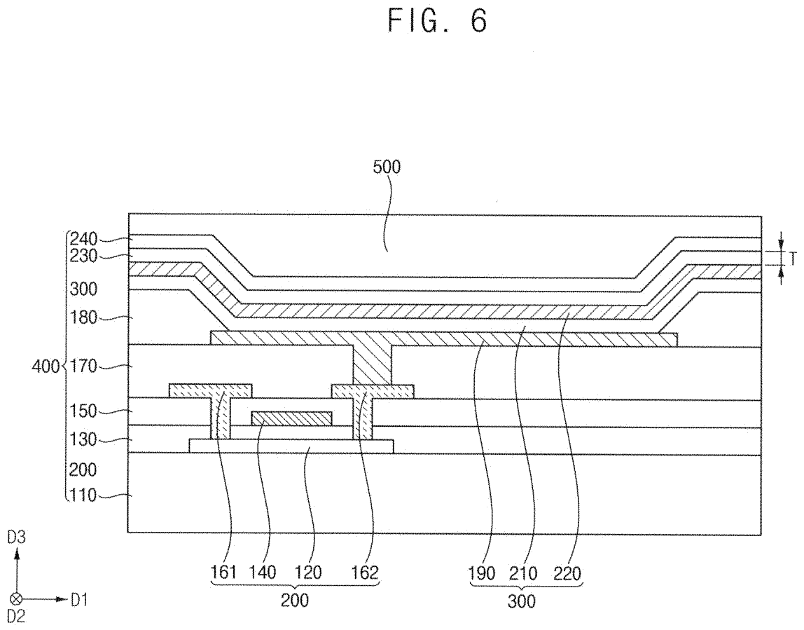

Referring back to FIG. 2, the sealing member 610 may be formed in the peripheral area PA on the base substrate 110. The sealing member 610 may include an organic material or the like. Referring to FIG. 6, the filling layer 500 may be formed on the anti-reflection layer 240. Specifically, the filling layer 500 may be formed on the display area DA and a portion of the peripheral area PA on the anti-reflection layer 240. The filling layer 500 may include a transparent material.

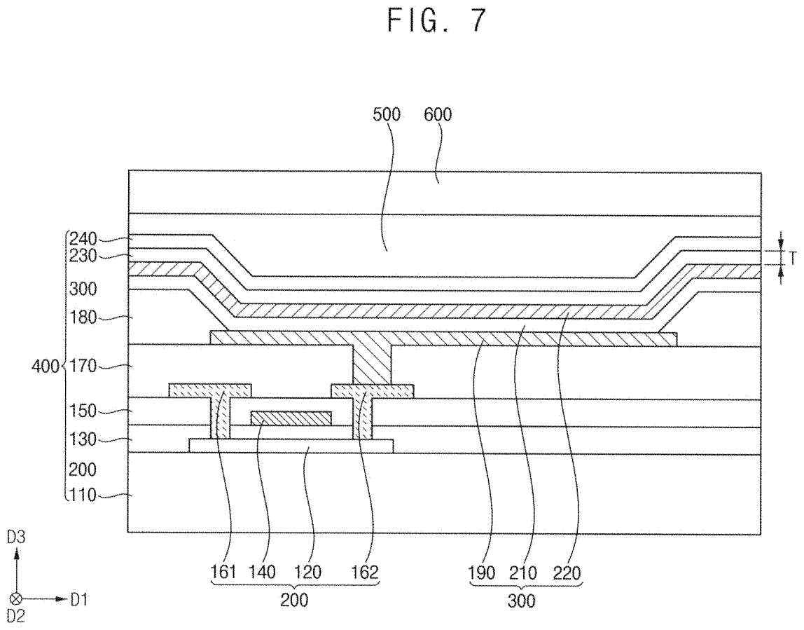

Referring to FIG. 7, the encapsulation substrate 600 may be positioned on the filling layer 500. Specifically, the encapsulation substrate 600 may contact an upper surface of the filling layer 500 and an upper surface of the sealing member 610. Thereafter, when a laser is irradiated to the sealing member 610, the sealing member 610 may be cured and the base substrate 110 and the encapsulation substrate 600 may be coupled to with each other. The encapsulation substrate 600 may include a transparent material or an opaque material.

Referring back to FIG. 3, the reflection adjusting layer 250 may be formed on the encapsulation substrate 600. The reflection adjusting layer 250 may be entirely formed on the encapsulation substrate 600. For example, the reflection adjusting layer 250 may include an organic material or the like. In another embodiment, after the organic layer is entirely formed on the encapsulation substrate 600, a plurality of reflection adjusting layers may be formed by patterning the organic layer.

Accordingly, the display device 100 illustrated in FIGS. 1, 2, and 3 may be manufactured.

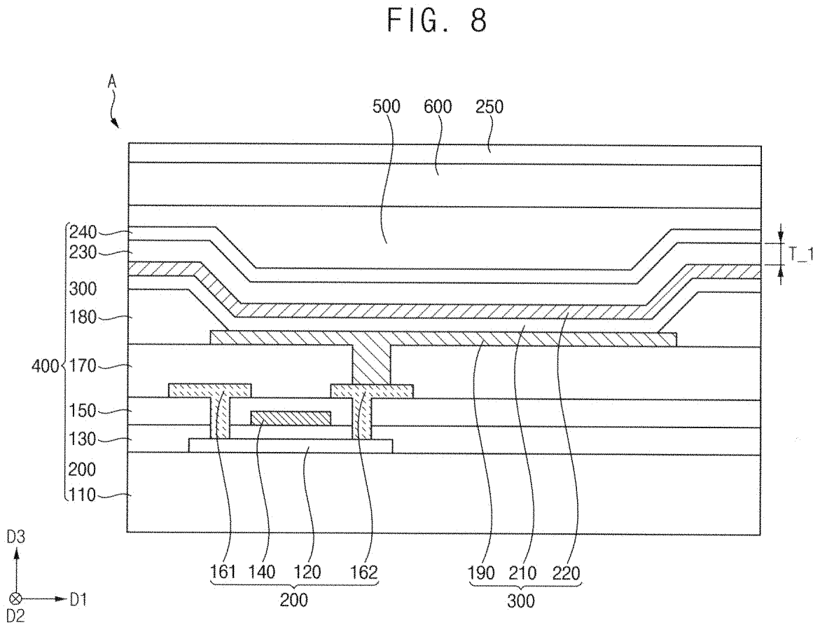

FIG. 8 is a cross-sectional view illustrating a display device according to another embodiment.

Referring to FIGS. 2 and 8, the display device 100 may include the display substrate 400, the filling layer 500, the sealing member 610, the encapsulation substrate 600, and the reflection adjusting layer 250. Here, the display substrate 400 may include the base substrate 110, the gate insulating layer 130, the driving element 200, the interlayer-insulating layer 150, the planarization layer 170, the pixel defining layer 180, the emission element 300, the capping layer 230, and the anti-reflection layer 240. The driving element 200 may include the active layer 120, the gate electrode 140, the source electrode 161, and the drain electrode 162. The emission element 300 may include the lower electrode 190, the emission layer 210, and the upper electrode. However, the display device 100 shown in FIG. 8 is substantially the same or similar as the display device 100 described with reference to FIG. 3 except for the thickness T_1 of the capping layer 230 and the refractive index of the filling layer 500. Hereinafter, overlapping descriptions will be omitted.

The filling layer 500 may be disposed on the anti-reflection layer 240. In an embodiment, the filling layer 500 may include titanium oxide, zirconium oxide, aluminum oxide, or the like. These may be used alone or in combination with each other. In this case, the refractive index of the filling layer 500 may be about 1.7 to about 2.1.

The refractive index of the filling layer 500 may be substantially the same as the refractive index of the anti-reflection layer 240 or the refractive index of the capping layer 230. In this case, the refractive index of the anti-reflection layer 240 or the refractive index of the capping layer 230 may be about 1.7 to about 2.1.

In an embodiment, the filling layer 500 may further include any one of a scatterer, a dye, and an ultraviolet absorber. Accordingly, the display quality of the display device 100 may be further improved.

In an embodiment, when the thickness T_1 of the capping layer 230 is about 630 Å to about 710 Å, the refractive index of the filling layer 500 may be about 1.7 to about 2.1. When the thickness T_1 of the capping layer 230 is less than about 630 Å or greater than about 710 Å in a case that the refractive index of the filling layer 500 may be about 1.7 to about 2.1, the reflectance of the display device 100 by external light may increase. In addition, when the refractive index of the filling layer 500 is less than about 1.7 or greater than about 2.1 in a case that the thickness T_1 of the capping layer 230 is about 630 Å to about 710 Å, the reflectance of the display device 100 by external light may increase.

In the display device 100 according to an embodiment of the present disclosure, the capping layer 230 may have the thickness of about 630 Å to about 710 Å, and the filling layer 500 may have the refractive index of about 1.7 to about 2.1. Accordingly, the reflectance of the display device 100 by external light may be reduced. Accordingly, the display quality of the display device 100 may be effectively improved.

Hereinafter, in the display device 100 according to an embodiment of the present disclosure, the reflectance of the display device 100 according to the thickness T, T_1 of the capping layer 230 and the refractive index of the filling layer 500 will be described.

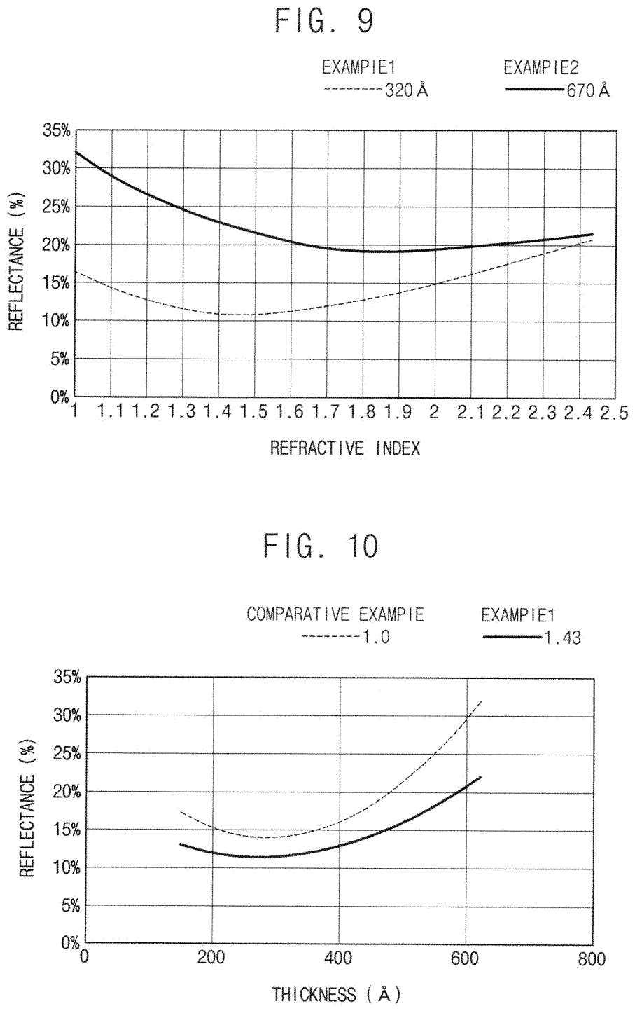

FIGS. 9 and 10 are diagrams illustrating reflectance of a display device obtained according to examples and comparative example. For example, FIG. 9 is a diagram illustrating reflectance of the display device 100 according to the refractive index of the filling layer 500 when the thickness T, T_1 of the capping layer 230 is constant. FIG. 10 is a diagram illustrating the reflectance of the display device 100 according to the thickness T, T_1 of the capping layer 230 when the refractive index of the filling layer 500 is constant.

Referring to FIG. 9, when the thickness T of the capping layer 230 is about 320 Å (Example 1) and the refractive index of the filling layer 500 is about 1.4, the reflectance of the display device 100 by external light may be about 10%. That is, when the thickness T of the capping layer 230 is about 320 Å, the reflectance value of the display device 100 by external light may become the minimum in a case that the refractive index of the filling layer 500 is about 1.4.

When the thickness T_1 of the capping layer 230 is about 670 Å (Example 2) and the refractive index of the filling layer 500 is about 1.9, the reflectance of the display device 100 by external light may be about 20%. That is, when the thickness T_1 of the capping layer 230 is about 670 Å, the reflectance value of the display device 100 by external light may become the minimum in a case that the refractive index of the filling layer 500 is about 1.9.

Referring to FIG. 10, when the refractive index of the filling layer 500 is about 1.43 (Example 1) and the thickness T of the capping layer 230 is about 300 Å, the reflectance of the display device 100 by external light may be about 11%. That is, when the refractive index of the filling layer 500 is about 1.43, the reflectance value of the display device 100 by external light may become the minimum, in a case that the thickness T of the capping layer 230 is about 300 Å.

On the other hand, when the refractive index of the filling layer 500 is about 1.0 (Comparative example) and the thickness T of the capping layer 230 is 300 Å, the reflectance of the display device 100 by external light may be about 14%. That is, when the thickness T of the capping layer 230 is constant, the reflectance value of the display device 100 by external light is relatively high as the refractive index of the filling layer 500 is low.

The present disclosure can be applied to various display devices that may include a display device. For example, the present disclosure can be applied to high-resolution smartphones, mobile phones, smart pads, smart watches, tablet PCs, in-vehicle navigation systems, televisions, computer monitors, notebook computers, or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a base substrate;
an emission element disposed on the base substrate;
a capping layer disposed on the emission element and having a thickness of about 280 angstroms (Å) to about 360 Å;
an anti-reflection layer disposed on the capping layer;
a filling layer disposed on the anti-reflection layer and having a refractive index of about 1.3 to about 1.6; and
an encapsulation substrate disposed on the filling layer.

2. The display device of claim 1, further comprising:
a reflection adjusting layer disposed on the encapsulation substrate.

3. The display device of claim 2, wherein the anti-reflection layer includes an inorganic material and the reflection adjusting layer includes an organic material.

4. The display device of claim 1, wherein the filling layer includes a transparent material.

5. The display device of claim 4, wherein the transparent material includes at least one selected from a group consisting of a silicone-based resin and an acrylic resin.

6. The display device of claim 4, wherein the filling layer further includes any one selected from a group consisting of a scatterer, a dye, and an ultraviolet absorber.

7. The display device of claim 1, further comprising:
a sealing member disposed between the base substrate and the encapsulation substrate and which couples the base substrate and the encapsulation substrate.

8. The display device of claim 7, wherein each of the base substrate and the encapsulation substrate includes a glass.

9. The display device of claim 1, wherein the emission element includes:
a lower electrode disposed on the base substrate;
an organic emission layer disposed on the lower electrode; and
an upper electrode disposed on the organic emission layer.

10. The display device of claim 1, wherein the refractive index of the filling layer is the same as a refractive index of the anti-reflection layer or a refractive index of the capping layer.

11. A display device comprising:
a base substrate;
an emission element disposed on the base substrate;
a capping layer disposed on the emission element and having a thickness of about 630 Å to about 710 Å;
an anti-reflection layer disposed on the capping layer;
a filling layer disposed on the anti-reflection layer and having a refractive index of about 1.7 to about 2.1; and
an encapsulation substrate disposed on the filling layer.

12. The display device of claim 11, further comprising:
a reflection adjusting layer disposed on the encapsulation substrate.

13. The display device of claim 12, wherein the anti-reflection layer includes an inorganic material and the reflection adjusting layer includes an organic material.

14. The display device of claim 11, wherein the filling layer includes a transparent material.

15. The display device of claim 14, wherein the transparent material includes at least one selected from a group consisting of a silicone-based resin and an acrylic resin.

16. The display device of claim 14, wherein the filling layer further includes any one selected from a group consisting of a scatterer, a dye, and an ultraviolet absorber.

17. The display device of claim 11, further comprising:
a sealing member disposed between the base substrate and the encapsulation substrate and which couples the base substrate and the encapsulation substrate.

18. The display device of claim 17, wherein each of the base substrate and the encapsulation substrate includes a glass.

19. The display device of claim 11, wherein the emission element includes:
a lower electrode disposed on the base substrate;
an organic emission layer disposed on the lower electrode; and
an upper electrode disposed on the organic emission layer.

20. The display device of claim 11, wherein the refractive index of the filling layer is the same as a refractive index of the anti-reflection layer or a refractive index of the capping layer.
